(19) United States
(12) Patent Application Publication
(10) Pub. No.: US 2025/0374682 A1
(43) Pub. Date: Dec. 4, 2025

(54) SEMICONDUCTOR CONTROLLED RECTIFIER

(71) Applicant: Renesas Design (UK) Limited, Bourne End (GB)

(72) Inventor: Gaurav SINGH, Chandler, AZ (US)

(73) Assignee: Renesas Design (UK) Limited, Bourne End (GB)

(21) Appl. No.: 18/679,705

(22) Filed: May 31, 2024

(51) Int. Cl. H01L 27/02; H01L 29/74

(52) U.S. Cl. CPC H10D 89/713; H10D 18/00

(57) ABSTRACT

A semiconductor controlled rectifier is provided. The rectifier includes an anode, a cathode, and a well including a first contact and a second contact. The anode is positioned between the first and second contacts, the first contact is arranged to provide a first current flow path from the first contact to the cathode via the anode, and the second contact is arranged to provide a second current flow path from the second contact to the cathode via the anode.

The present disclosure relates to a semiconductor controlled rectifier. In particular, the present disclosure relates to a semiconductor controlled rectifier that may be implemented in silicon and may provide low voltage triggering for protection against electrostatic discharge.

### BACKGROUND

Electrostatic discharge is a process under which electric charge that has built up on a material is suddenly and unexpectedly discharged. Electrostatic discharge can be damaging to electrical circuits, where the resultant large current flow can exceed the tolerances of the components. Therefore, integrated circuits will typically implement some form of electrostatic discharge protection.

One such system for protecting against electrostatic discharge is a semiconductor controlled rectifier, which can provide a safe current flow path for electrical discharge once a threshold property, such as a threshold voltage, has been reached. Semiconductor controlled rectifiers are typically implemented using silicon, and are referred to as silicon controlled rectifiers (SCR).

Prior art low-voltage triggering silicon controlled rectifiers (LVTSCR) are presented in:
Chatterjee and T. Polgreen, “A low-voltage triggering SCR for on-chip ESD protection at output and input pads”, IEEE Electron Device Lett., vol. 12, no. 1, pp. 21-22, January 1991.
M.-D. Ker, C.-Y. Wu and H.-H. Chang, “Complementary-LVTSCR ESD protection circuit for submicron CMOS VLSI/ULSI”, IEEE Trans. Electron Devices, vol. 43, no. 4, pp. 588-598, April 1996.

### SUMMARY

It is desirable to provide an improved semiconductor controlled rectifier. For example, by providing a semiconductor controlled rectifier that provides one or more of a low capacitance, low leakage current, low footprint and high robustness, when compared to known systems.

According to a first aspect of the disclosure there is provided a semiconductor controlled rectifier including an anode, a cathode, and a well including a first contact and a second contact, wherein the anode is positioned between the first and second contacts, the first contact is arranged to provide a first current flow path from the first contact to the cathode via the anode, and the second contact is arranged to provide a second current flow path from the second contact to the cathode via the anode.

Optionally, the anode includes a first emitter.

Optionally, the first emitter is a P+emitter.

Optionally, the anode includes a first portion and a second portion, the first portion having a greater width than the second portion.

Optionally, the anode includes a third portion having a greater width than the second portion.

Optionally, the first portion, the second portion and/or the third portion are substantially rectangular.

Optionally, the first and third portions are of equal width.

Optionally, the second portion is sandwiched between the first and second portions.

Optionally, the first contact is substantially adjacent to the first portion of the anode and the second contact is substantially adjacent to the third portion of the anode.

Optionally, the first contact and first portion are configured, by their positioning, to provide the first current flow path from the first contact to the cathode via the first portion of the anode and/or the second contact and the first portion are configured, by their positioning, to provide the second current flow path from the second contact to the cathode via the third portion of the anode.

Optionally, the length of at least one of the first, second and third portions is approximately 15 μm.

Optionally, the semiconductor controlled rectifier includes a first metal oxide semiconductor field effect transistor (MOSFET) including a first drain, a first gate and a first source, wherein the cathode includes the first source of the first MOSFET.

Optionally, the first gate is a poly gate.

Optionally, the first MOSFET is a first n-type MOSFET (NMOS).

Optionally, the cathode includes a second emitter, the second emitter being the first source of the first MOSFET.

Optionally, the second emitter is a first N+ emitter.

Optionally, the first drain at least partially overlaps the well in a first overlapping region.

Optionally, the first overlapping region is substantially equidistant from the first and second contacts.

Optionally, at least a portion of the first drain has a length that is less than the length of the first source.

Optionally, the length of the first drain within the first overlapping region is approximately 15 μm.

Optionally, the semiconductor controlled rectifier includes a second metal oxide semiconductor field effect transistor (MOSFET) including a second drain, a second gate and a second source, wherein the cathode includes the second source of the second MOSFET.

Optionally, the first gate is a first poly gate and/or the second gate is a second poly gate.

Optionally, the first MOSFET is a first n-type MOSFET (NMOS) and/or the second MOSFET is a second n-type MOSFET (NMOS).

Optionally, the cathode includes a third emitter, the third emitter being the second source of the second MOSFET.

Optionally, the third emitter is a second N+ emitter.

Optionally, the second drain at least partially overlaps the well in a second overlapping region.

Optionally, the first overlapping region is substantially equidistant from the first and second contacts and/or the second overlapping region is substantially equidistant from the first and second contacts.

Optionally, at least a portion of the first drain has a length that is less than the length of the first source and/or at least a portion of the second drain has a length that is less than the length of the second source.

Optionally, the length of the first drain within the first overlapping region is approximately 15 μm and/or the length of the second drain within the second overlapping region is approximately 15μm.

Optionally, the well is an N well, the first contact includes a first N+ contact and the second contact includes a second N+ contact.

Optionally, the semiconductor controlled rectifier has a surface area less than approximately 929.5 mm².

Optionally, the first and second contacts are symmetrically positioned at opposite sides of the anode.

Optionally, the semiconductor controlled rectifier is configured to protect against electrostatic discharge by permitting charge to flow via the first and the second current flow paths when a triggering voltage exceeds a threshold voltage value.

Optionally, the semiconductor controlled rectifier includes a substrate.

Optionally, the substrate is a P-type substrate.

Optionally, the semiconductor controlled rectifier is a silicon controlled rectifier.

According to a second aspect of the disclosure there is provided a method of providing a semiconductor controlled rectifier including providing an anode, a cathode, and a well including a first contact and a second contact, wherein the anode is positioned between the first and second contacts, the first contact is arranged to provide a first current flow path from the first contact to the cathode via the anode, and the second contact is arranged to provide a second current flow path from the second contact to the cathode via the anode.

It will be appreciated that the method of the second aspect may include using and/or providing features set out in the first aspect and can incorporate other features as described herein.

### BRIEF DESCRIPTION OF THE DRAWINGS

The disclosure is described in further detail below by way of example and with reference to the accompanying drawing in which:

FIG. 1A is a top down schematic of a known silicon controlled rectifier (SCR), FIG. 1B is a cross section schematic of the SCR through A-A, as shown in FIG. 1A, FIG. 1C is a further cross section schematic of the SCR through B-B as shown in FIG. 1A;

FIG. 2 is a top down schematic of a known silicon controlled rectifier (SCR);

FIG. 3A is a top down schematic of a semiconductor controlled rectifier in accordance with a first embodiment of the present disclosure, FIG. 3B is a cross section of the semiconductor controlled rectifier through A-A as is shown in FIG. 3A, FIG. 3C is a cross section of the semiconductor controlled rectifier through B-B-as is shown in FIG. 3A;

FIG. 4A is a top-down schematic of a semiconductor controlled rectifier in accordance with a second embodiment of the present disclosure, FIG. 4B is a cross section of the semiconductor controlled rectifier through A-A as is shown in FIG. 4A, FIG. 4C is a cross section of the semiconductor controlled rectifier through B-B as is shown in FIG. 4A;

FIG. 5A is a top-down schematic of a semiconductor controlled rectifier in accordance with a third embodiment of the present disclosure, FIG. 5B is a cross section of the semiconductor controlled rectifier through A-A as is shown in FIG. 5A, FIG. 5C is a cross section of the semiconductor controlled rectifier through B-B as is shown in FIG. 5A;

FIG. 6A is a top-down schematic of a semiconductor controlled rectifier in accordance with a fourth embodiment of the present disclosure, FIG. 6B is a cross section of the semiconductor controlled rectifier through A-A as is shown in FIG. 6A, FIG. 6C is a cross section of the semiconductor controlled rectifier through B-B as is shown in FIG. 6A;

FIG. 7 is a top-down schematic of a semiconductor controlled rectifier in accordance with a fifth embodiment of the present disclosure; and

FIG. 8A is a graph showing measured for practical implementations of the SCR of FIG. 7 and the known SCR of FIG. 2, FIG. 8B is a graph showing the results presented in FIG. 8A over a reduced scale, FIG. 8C is a graph showing further simulation results for practical implementations of the SCR of FIG. 7 and the known SCR of FIG. 2, FIG. 8D is a graph showing further simulation results for practical implementations of the SCR of FIG. 7 and the known SCR of FIG. 2.

### DETAILED DESCRIPTION

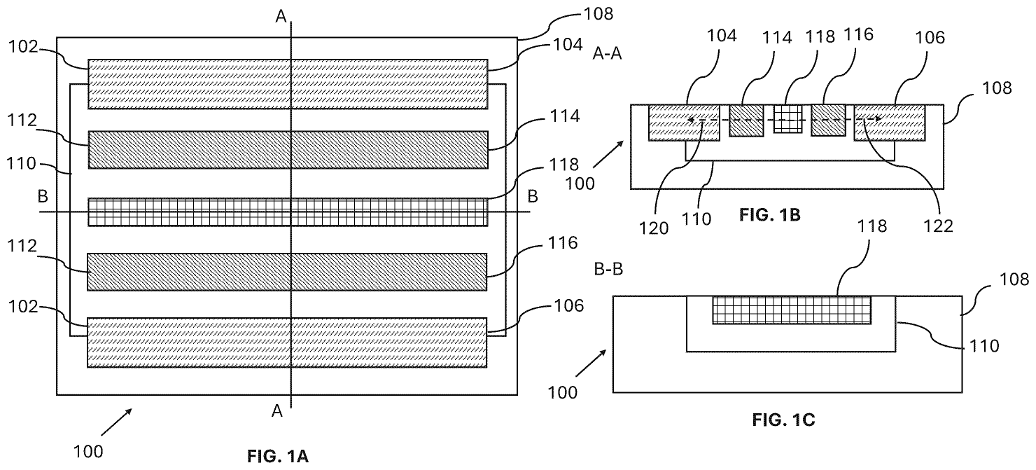

FIG. 1A is a top down schematic of a known silicon controlled rectifier (SCR) 100 comprising a cathode 102 formed by two sources 104, 106 of n-type metal oxide semiconductor field effect transistors (MOSFET). The SCR 100 further comprises a substrate 108 and an N well 110 within the substrate 108. The sources 104, 106 each overlap part of the N well 110.

The N well 110 is a region of semiconductor material having n-type doping within the substrate 108, as will be clear to the skilled person.

The SCR 100 further comprises an anode 112 that is formed by two strips of P+ emitter 114, 116. The SCR further comprises a N+ contact 118 of the N well 110, that runs across the length of the device.

It will be appreciated that “+” denotes a high level of doping as is convention, and as will be clear to the skilled person.

FIG. 1B is a cross section schematic of the SCR 100 through A-A, as shown in FIG. 1A. A current path 120 is shown from the N+ contact 118 to the drain 104 via the P+ emitter 114. A current path 122 is shown from the N+ contact 118 to the drain 106 via the P+ emitter 116.

FIG. 1C is a further cross section schematic of the SCR through B-B as shown in FIG. 1A.

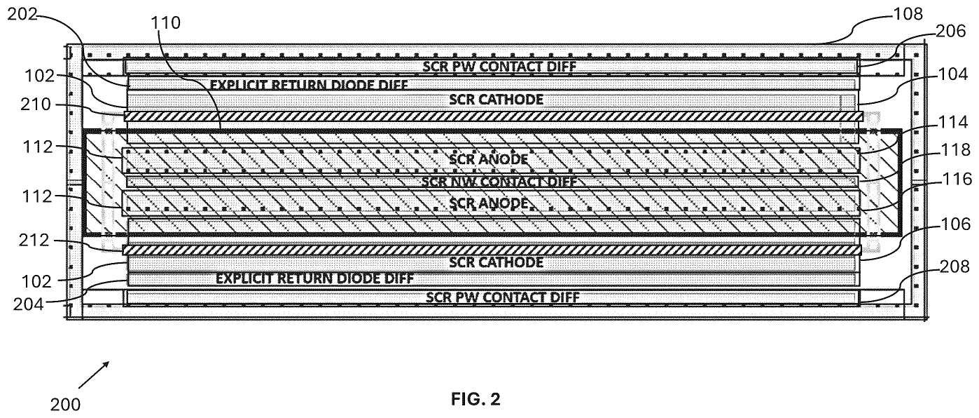

FIG. 2 is a top down schematic of a known silicon controlled rectifier (SCR) 200. The SCR 200 shares features with the SCR 100 and further comprises explicit diodes 202, 204 for negative zap; P well contacts 206, 208; and gates 210, 212.

The total size of the SCR 200 is approximately 929.5 mm². The SCR 200 exhibits It2 levels of 61 mA/μm of robustness. “It2” is a metric of robustness of the device, also called failure current level. The higher the number the more robust the device is.

The triggering current It1 is 40 mA and the triggering voltage Vt1 is 5.1V. The triggering voltage is the voltage across the N+ contact 118 to the cathode 102 at which the SCR 200 will be triggered and the discharging current will be permitted to flow, thereby protecting against electrostatic discharge of a coupled device. Prior to the triggering of the SCR 200, the current will gradually increase and peaks at the triggering current at the triggering voltage. Additionally, there are indications of non-uniform triggering of the SCR 200 around a holding voltage. The holding voltage is the voltage across the device just after it has been triggered.

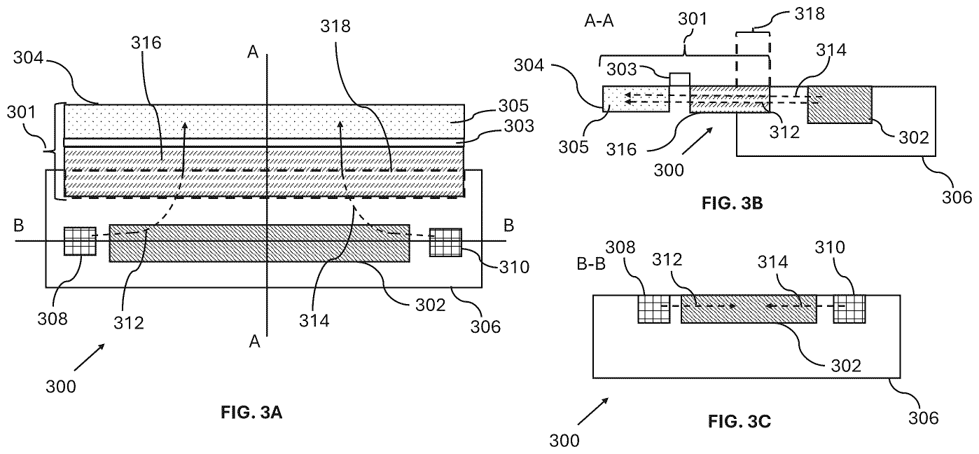

FIG. 3A is a top down schematic of a semiconductor controlled rectifier 300 in accordance with a first embodiment of the present disclosure. The semiconductor controlled rectifier 300 comprises an anode 302, a cathode 304 and a well 306 comprising a contact 308 and a contact 310. In a specific embodiment, the semiconductor controlled rectifier 300 may be a silicon controlled rectifier (SCR).

The contacts 308, 310 may be diffusion contacts. Diffusion contacts are formed as part of the semiconductor material which in contrast with, for example, metal contacts. It should be noted that any component formed as part of the semiconductor material through a diffusion process may be referred to as a “diffusion”. For example, the anode 302 may be referred to as a diffusion anode or an anode diffusion.

Further embodiments of the semiconductor controlled rectifier 300 may include any of the features described in relation to any of the other semiconductor controlled rectifier embodiments as described herein in accordance with the understanding of the skilled person.

FIG. 3B is a cross section of the semiconductor controlled rectifier 300 through A-A as is shown in FIG. 3A. FIG. 3C is a cross section of the semiconductor controlled rectifier 300 through B-B- as is shown in FIG. 3A.

The anode 302 is positioned between the contacts 308, 310, for example as shown in FIG. 3A and FIG. 3C. The contact 308 is arranged to provide a current flow path 312 from the contact 308 to the cathode 304 via the anode 302. The contact 310 is arranged to provide a current flow path 314 from the contact 310 to the cathode 304 via the anode 302.

The anode 302 may comprise an emitter, such as a P+ emitter. The semiconductor controlled rectifier 300 may comprise a metal oxide semiconductor field effect transistor (MOSFET) 301. The MOSFET 301 comprises a drain 316, a gate 303 and a source 305, where the cathode 304 comprises the source 305. The gate 303 may be a poly gate. The MOSFET 301 may, for example, be an n-type MOSFET (NMOS).

The cathode 304 may comprise an emitter, with the emitter being the source 305. The emitter may be an N+ emitter.

The well 306 may be an N well and at least one of the contacts 308, 310 may comprise an N+ contact.

In a specific embodiment, the anode diffusion 302 is the P+ emitter of a PNP bipolar, while cathode 304 is the N+ emitter of a NPN bipolar. Together the PNP bipolar and the NPN bipolar are coupled to form the semiconductor controlled rectifier.

In the present embodiment, the contacts 308, 310 are positioned on opposite sides of the anode 302. The contacts 308, 310 may be symmetrically positioned such that in relation to the positioning of the contacts 308, 310 a line of symmetry runs vertically down the anode 302 (for example the A-A line).

The drain 316 may, at least partially, overlap the well 306 in an overlapping region 318. The overlapping region 318 may be equidistant from the contacts 308, 310.

The semiconductor controlled rectifier 300 may comprise a substrate (not shown) with the well 306 being formed in the substrate. The substrate may, for example, be a P-type substrate.

It will be appreciated that in further specific embodiments, the semiconductor controlled rectifier of any of the embodiments described herein may comprise a substrate with the well 306 and/or additional features being formed in the substrate, in accordance with the understanding of the skilled person. The substrate may, for example, be a P-type substrate.

In the present example, and when compared with the known SCRs 100, 200, there are now provided two N+ contacts (the contacts 308, 310) with a reduced size when compared to the single N+ contact 118. The smaller size increases the effective well resistance and hence results in smaller device with better triggering characteristics.

In summary, embodiments of the present disclosure are low voltage triggering semiconductor controlled rectifiers (LVTSCR) that are created using an inherent MOSFET. MOSFETs may comprise two diffused regions separated by a poly gate. One of the diffused regions is called the “drain” and the other is called the “source”. In the LVTSCR the source also acts like emitter of an NPN bipolar and the drain overlaps with the well to help in triggering of the SCR.

In a specific embodiment, the semiconductor controlled rectifier 300 may be applied to protect against electrostatic discharge (ESD) by permitting charge to flow via the current flow paths 312, 314 when a triggering voltage exceeds a threshold value.

As the contacts 308, 310 positioned symmetrically at opposite sides of the anode 302, conduction symmetry is maintained, as shown by the current flow paths 312, 314. This increases the effective N well resistance of the well 306 as experienced by the trigger current, without impacting the size of the device. Hence lowering the triggering voltage.

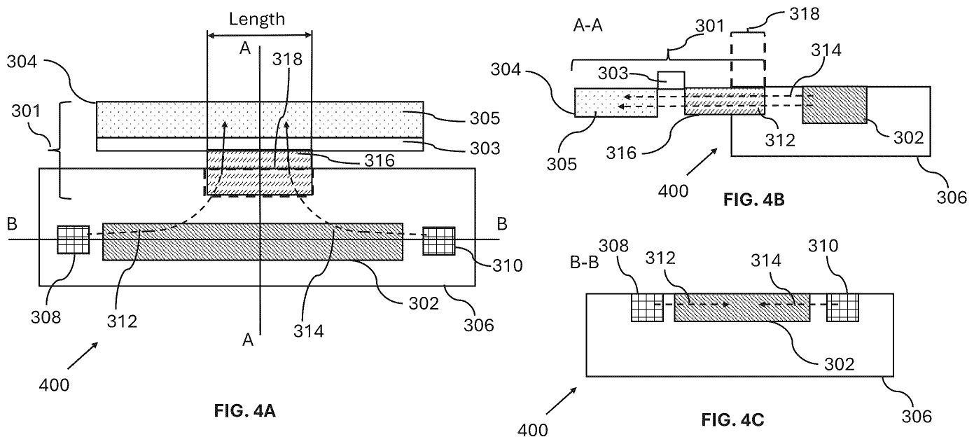

FIG. 4A is a top-down schematic of a semiconductor controlled rectifier 400 in accordance with a second embodiment of the present disclosure. Further embodiments of the semiconductor controlled rectifier 400 may include any of the features described in relation to any of the other semiconductor controlled rectifier embodiments as described herein in accordance with the understanding of the skilled person.

FIG. 4B is a cross section of the semiconductor controlled rectifier 400 through A-A as is shown in FIG. 4A. FIG. 4C is a cross section of the semiconductor controlled rectifier 400 through B-B as is shown in FIG. 4A.

In the present embodiment, the drain 316 of the NMOS has a reduced length (labelled “Length” in FIG. 4A) in a central portion that overlaps the well 306 when compared with the semiconductor controlled rectifier 300. The length of the drain 316 is less than the length of the source 305. In a specific embodiment, the length of the drain 316 may be approximately 15 μm.

In the embodiment illustrated in FIG. 4A, the whole of the drain 316 has a substantially uniform length that is less than the length of the source 305. In a further embodiment there may only be a portion of the drain 316 that has a length that is less than the length of the source 305.

For example, in a further embodiment, there may be a first portion of the drain 316 having a length that is less that the length of the source 305. A second portion of the drain 316 may have a length that is greater than the length of the first portion of the drain 316. The second portion of the drain 316 may have a length that is less than, equal to, or greater than the length of the source 305. The second portion of the drain 316 may, for example, be adjacent to the gate 303, with the first portion overlapping the well 306.

In the present embodiment, the portion of the drain 316 of the NMOS overlapping the N well 306 is reduced to 15 μm in the centre of the semiconductor controlled rectifier 400 only, instead of total length of the silicon controlled rectifier 400. This forces the trigger current in the N well 306 to flow in the direction as shown by the current flow paths 312, 314 underneath the anode's 302 P+ emitter diffusion.

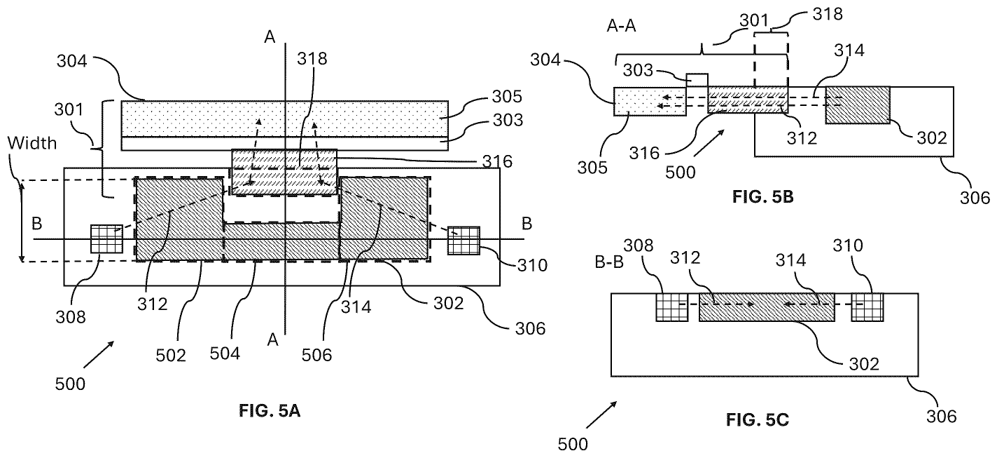

FIG. 5A is a top-down schematic of a semiconductor controlled rectifier 500 in accordance with a third embodiment of the present disclosure. Further embodiments of the semiconductor controlled rectifier 500 may include any of the features described in relation to any of the other semiconductor controlled rectifier embodiments as described herein in accordance with the understanding of the skilled person.

FIG. 5B is a cross section of the semiconductor controlled rectifier 500 through A-A as is shown in FIG. 5A. FIG. 5C is a cross section of the semiconductor controlled rectifier 500 through B-B as is shown in FIG. 5A.

In the present embodiment, the anode 302 is divided into a plurality of portions. Specifically, there is a first portion 502, a second portion 504 and a third portion 506. In the present embodiment, the widths of the first and third portions 502, 506 are each greater than the width of the second portion 504. Furthermore, the widths of the first and third portions 502, 506 are approximately equal. The width of the first portion 502 is labelled as “Width” in FIG. 5A.

All portions 502, 504, 506 are substantially rectangular as viewed in the top-down view of FIG. 5A. The length of one or more of the portions 502, 504, 506 of the anode 302 may be approximately 15 μm.

As can be observed in FIG. 5A, the contact 308 is adjacent to the first portion 502 of the anode 302 such that the current flow path 312 from the contact 308 to the cathode 304 is via the first portion 502.

Additionally, the contact 310 is adjacent to the third portion 506 of the anode 302 such that current flow path 314 from the contact 310 to the cathode 304 is via the third portion 506.

In the present embodiment, a single strip of P+ emitter diffusion is used (the anode 302). The half-dumbbell shape of the anode 302 enables the area over the N well 306 where the drain 316 of the NMOS overlaps to be increased when compared with the known systems of FIG. 1A-FIG. 1C and FIG. 2. This increases the effective emitter area for the semiconductor controlled rectifier 500 to be engaged during the conduction and spreading of current filaments, without impacting the overall device size.

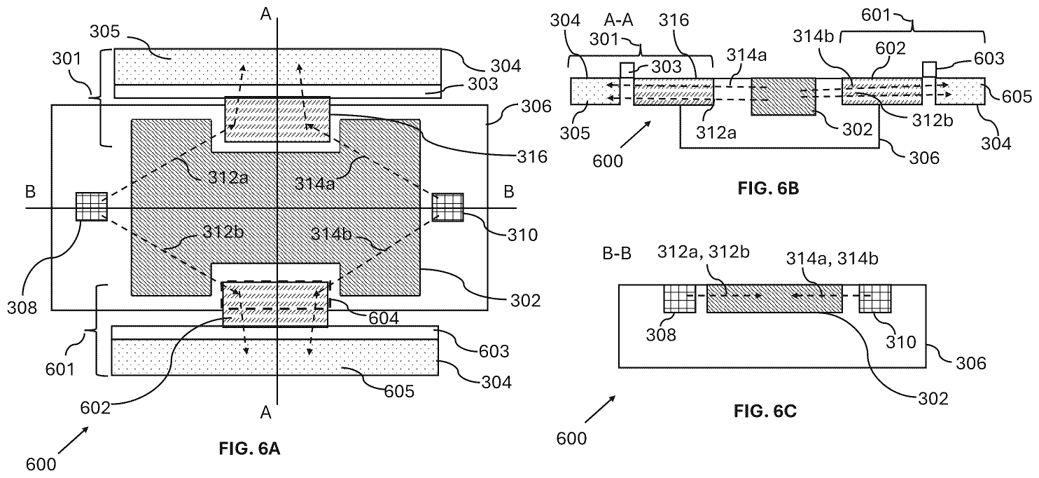

FIG. 6A is a top-down schematic of a semiconductor controlled rectifier 600 in accordance with a fourth embodiment of the present disclosure. Further embodiments of the semiconductor controlled rectifier 600 may include any of the features described in relation to any of the other semiconductor controlled rectifier embodiments as described herein in accordance with the understanding of the skilled person.

FIG. 6B is a cross section of the semiconductor controlled rectifier 600 through A-A as is shown in FIG. 6A. FIG. 6C is a cross section of the semiconductor controlled rectifier 600 through B-B as is shown in FIG. 6A.

In the present embodiment, the semiconductor controlled rectifier 600 comprises a metal oxide semiconductor field effect transistor (MOSFET) 601. The MOSFET 601 comprises a drain 602, a gate 603, and a source 605, where the cathode 304 comprises the source 605. The gate 603 may be a poly gate. The MOSFET 601 may, for example, be an n-type MOSFET (NMOS).

The cathode 304 may comprise a first emitter, being the source 305 and a second emitter, being the source 605. The emitters may be N+ emitters.

The drain 602 at least partially overlaps the well 306 in an overlapping region 604. The length of the drain 602 may be approximately 15 μm.

In the embodiment illustrated in FIG. 6A, the whole of the drain 602 has a substantially uniform length that is less than the length of the source 605. In a further embodiment there may only be a portion of the drain 602 that has a length that is less than the length of the source 605.

In the present embodiment, the inclusion of the drain 602 means that the current flow path 312 comprises two sub-paths 312a, 312b; and the current flow path 314 comprises two sub-paths 314a, 314b.

The surface area of the semiconductor controlled rectifier 600 may be less than that of the known system presented in FIG. 2. Specifically, the semiconductor controlled rectifier 600 may have a surface area less than 929.5 mm².

In the present embodiment, a single strip of P+ emitter diffusion is used (the anode 302). The dumbbell shape of the anode 302 enables the area over the N well 306 where the drains 316, 602 overlap to be increased when compared with the known systems of FIGS. 1A-1C and FIG. 2. This increases the effective emitter area for the semiconductor controlled rectifier 600 to be engaged during the conduction and spreading of current filaments, without impacting the overall device size.

In further embodiments, the dimensions of one or both of the drains 316, 602 and/or the dimensions of the P+ emitter 302 contacts can be varied depending on technology parameters.

In further embodiments, further gate or substrate triggering mechanisms may be used for one of both of the NMOSs to alter the triggering characteristics of the overall structure of the semiconductor controlled rectifier 600.

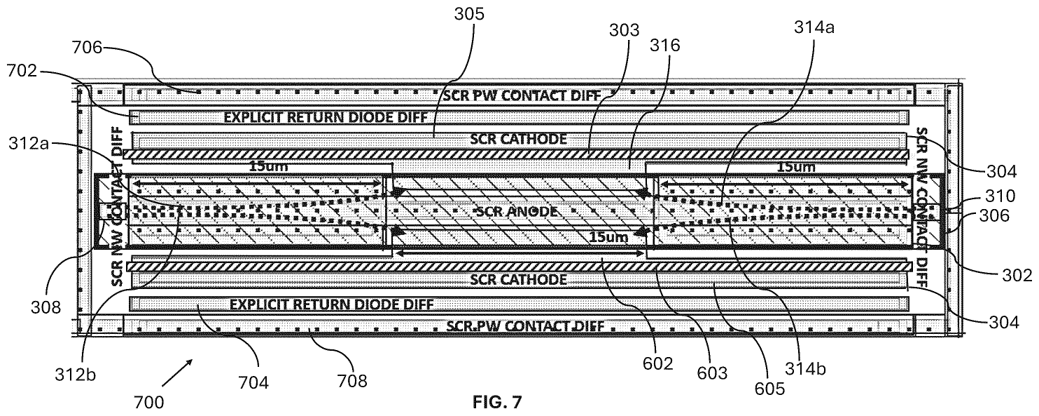

FIG. 7 is a top-down schematic of a semiconductor controlled rectifier 700 in accordance with a fifth embodiment of the present disclosure.

The semiconductor controlled rectifier 700 shares features with the semiconductor controlled rectifier 600 and further comprises explicit diodes 702, 704 for negative zap, and P well contacts 706, 708. The semiconductor controlled rectifier 700 is a silicon controlled rectifier (SCR) having a total device size of 776.4 mm², which is 17% smaller in area as compared to the SCR 200.

The SCR 700 functions as a low voltage triggering SCR (LVTSCR) such that the avalanche charge induced by one or both of the NMOS devices (the drains 316, 602) flows under the emitter (the anode 302) towards one or both of the NWELL contacts (the contacts 308, 310) that it results in homogeneous and more efficient triggering of the SCR 700. Charge flow is in the opposite direction of current because the polarity of the generated charge is negative.

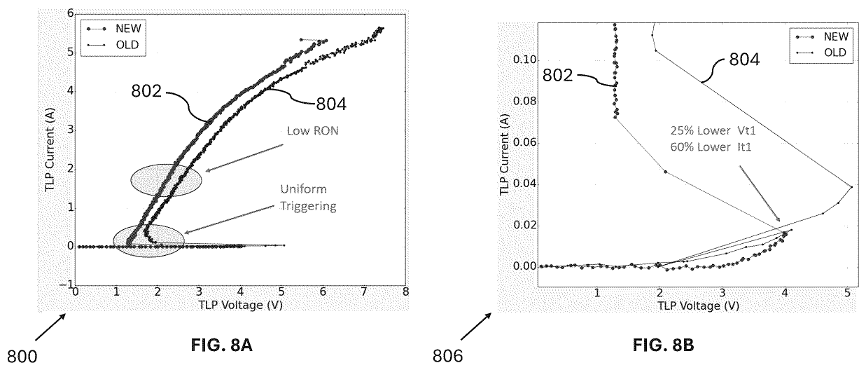

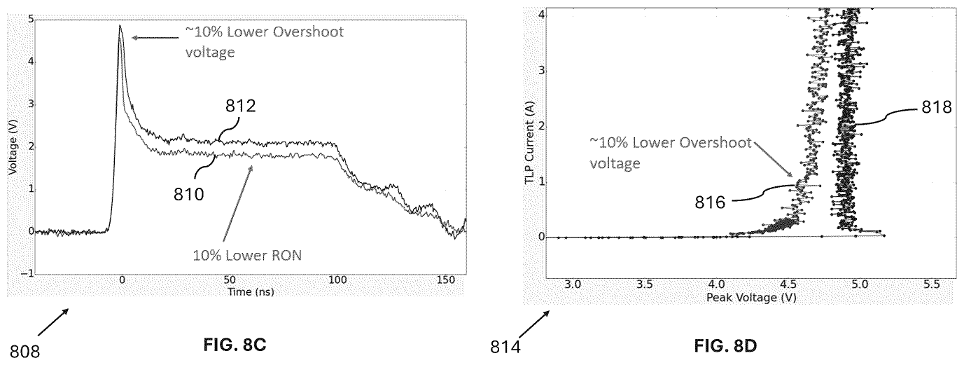

FIG. 8A is a graph 800 showing measured results for practical implementations of the SCR 700 (a trace 802) and the known SCR 200 (a trace 804). FIG. 8B is a graph 806 showing the results presented in FIG. 8A over a reduced scale.

It is evident from the IV characteristics around the triggering and holding voltage region that the SCR 700 shows much more definitive triggering characteristics and no signs of uncertainty like the SCR 200 device IV curve. It is also evident in the zoomed plot that the SCR 700 has much better triggering characteristics and shows 25% improvement on triggering voltage Vt1 and 60% improvement on triggering current It1. This can be very critical for low energy ESD events or in case of a parallel capacitive load scenario.

FIG. 8C is a graph 808 showing further simulation results for practical implementations of the SCR 700 (a trace 810) and the known SCR 200 (a trace 812). FIG. 8D is a graph 814 showing further simulation results for practical implementations of the SCR 700 (a trace 816) and the known SCR 200 (a trace 818).

FIG. 8C shows transient characteristics at 1A of TLP ESD current. The SCR 700 has a faster transient response in triggering or turning ON hence resulting in 10% less overshoot (peak voltage). Also, the SCR 700 has 10% lower RON, thanks to its substantially uniform triggering. The modifications to the SCR 700 over the SCR 200 result in improvements that provide a compact LVTSCR with much better characteristics, as shown by the results presented in FIGS. 8A-8D.

Embodiments of the present disclosure use layout modification and placement techniques to manipulate the charge flowing paths in order to provide an improved semiconductor controlled rectifier. In summary, embodiments of the present disclosure provide an optimized area solution for a very high robustness, low capacitance, low leakage ESD clamp with superior transient characteristics when compared to known systems.

In summary, embodiments of the present disclosure can provide a LVTSCR with one or more of the following advantages over known LVTSCRs:
1) Higher current density achieved hence lower area footprint;
2) Lower Triggering voltage Vt1
3) Lower triggering current It1;
4) Faster Turn-ON speed;
5) Lower overshoot voltage;
6) Homogeneous and uniform turn ON and hence better triggering characteristics for low energy ESD events;
7) No external triggering mechanism is required.

Common features between Figures are represented by common reference numerals and common variables.

Various improvements and modifications may be made to the above without departing from the scope of the disclosure.

1. A semiconductor controlled rectifier comprising:
an anode;
a cathode; and
a well comprising a first contact and a second contact;
wherein:
the anode is positioned between the first and second contacts;
the first contact is arranged to provide a first current flow path from the first contact to the cathode via the anode; and
the second contact is arranged to provide a second current flow path from the second contact to the cathode via the anode.

2. The semiconductor controlled rectifier of claim 1, wherein the anode comprises a first emitter.

3. The semiconductor controlled rectifier of claim 2, wherein the first emitter is a P+ emitter.

4. The semiconductor controlled rectifier of claim 1, wherein the anode comprises a first portion and a second portion, the first portion having a greater width than the second portion.

5. The semiconductor controlled rectifier of claim 4, wherein the anode comprises a third portion having a greater width than the second portion.

6. The semiconductor controlled rectifier of claim 5, where the first portion, the second portion and/or the third portion are substantially rectangular.

7. The semiconductor controlled rectifier of claim 5, wherein the first and third portions are of equal width.

8. The semiconductor controlled rectifier of claim 7, wherein the second portion is sandwiched between the first and second portions.

9. The semiconductor controlled rectifier of claim 8, wherein the first contact is substantially adjacent to the first portion of the anode and the second contact is substantially adjacent to the third portion of the anode.

10. The semiconductor controlled rectifier of claim 8, wherein the first contact and first portion are configured, by their positioning, to provide the first current flow path from the first contact to the cathode via the first portion of the anode and/or the second contact and the first portion are configured, by their positioning, to provide the second current flow path from the second contact to the cathode via the third portion of the anode.

11. The semiconductor controlled rectifier of claim 1, further comprising:
a first metal oxide semiconductor field effect transistor (MOSFET) comprising a first drain, a first gate and a first source;
wherein the cathode comprises the first source of the first MOSFET.

12. The semiconductor controlled rectifier of claim 11, wherein the first MOSFET is a first n-type MOSFET (NMOS).

13. The semiconductor controlled rectifier of claim 12, wherein the cathode comprises a second emitter, the second emitter being the first source of the first MOSFET.

14. The semiconductor controlled rectifier of claim 13, wherein the second emitter is a first N+ emitter.

15. The semiconductor controlled rectifier of claim 11, wherein the first drain at least partially overlaps the well in a first overlapping region.

16. The semiconductor controlled rectifier of claim 15, wherein the first overlapping region is substantially equidistant from the first and second contacts.

17. The semiconductor controlled rectifier of claim 11, wherein at least a portion of the first drain has a length that is less than the length of the first source.

18. The semiconductor controlled rectifier of claim 11, further comprising:
a second metal oxide semiconductor field effect transistor (MOSFET) comprising a second drain, a second gate and a second source;
wherein the cathode comprises the second source of the second MOSFET.

19. The semiconductor controlled rectifier of claim 18, wherein the second drain at least partially overlaps the well in a second overlapping region.

20. The semiconductor controlled rectifier of claim 19, wherein at least a portion of the first drain has a length that is less than the length of the first source and/or at least a portion of the second drain has a length that is less than the length of the second source.

21. The semiconductor controlled rectifier of claim 1, wherein the well is an N well, the first contact comprises a first N+ contact and the second contact comprises a second N+ contact.

22. The semiconductor controlled rectifier of claim 1, wherein the first and second contacts are symmetrically positioned at opposite sides of the anode.

23. The semiconductor controlled rectifier of claim 1, wherein the rectifier is configured to protect against electrostatic discharge by permitting charge to flow via the first and the second current flow paths when a triggering voltage exceeds a threshold voltage value.

24. The semiconductor controlled rectifier of claim 1, further comprising a substrate.

25. A method of providing a semiconductor controlled rectifier, the method comprising:
providing an anode, a cathode, and a well comprising a first contact and a second contact;
wherein:
the anode is positioned between the first and second contacts;
the first contact is arranged to provide a first current flow path from the first contact to the cathode via the anode; and
the second contact is arranged to provide a second current flow path from the second contact to the cathode via the anode.
